(19) United States
(12) Patent Application Publication
(10) Pub. No.: US 2026/0153448 A1
(43) Pub. Date: Jun. 4, 2026

(54) Methods And Systems For Measurement Of Large Dimension Structures Fabricated Using Semiconductor Processing Techniques

(71) Applicants: Houssam Chouaib, Milpitas, CA (US); Shankar Krishnan, Cupertino, CA (US)

(72) Inventors: Houssam Chouaib, Milpitas, CA (US); Shankar Krishnan, Cupertino, CA (US)

(21) Appl. No.: 19/385,590

(22) Filed: Nov. 11, 2025

Related U.S. Application Data
(60) Provisional application No. 63/727,757, filed on Dec. 4, 2024.

(51) Int. Cl. G01N 21/88; G01N 21/47; G01N 21/956

(52) U.S. Cl. CPC G01N 21/8806; G01N 21/47; G01N 21/956

(57) ABSTRACT

Methods and systems for performing accurate and robust scatterometry based measurements of relatively large dimension structures fabricated using semiconductor fabrication processes are presented herein. In some examples, relatively large dimension structures include spiral-shaped features that are not periodic. In one aspect, one or more relatively large dimension device structures are fabricated on a specimen along with one or more proxy metrology targets. Each of the one or more proxy metrology targets are spatially periodic and include an array of nominally identical curved segments characterized by a radius of curvature. The radius of curvature associated with each of the plurality of proxy metrology targets corresponds to the radius of curvature of each of the plurality of turnings of a spiral-shaped device structure. In preferred embodiments, the film stack and line/space ratio associated with each of the proxy metrology targets is the same as the device structures.

### CROSS REFERENCE TO RELATED APPLICATION

The present application for patent claims priority under 35 U.S.C. § 119 from U.S. provisional patent application Ser. No. 63/727,757, entitled “Optical Metrology for Silicon Hairspring and MEMS Energy Harvester,” filed Dec. 4, 2024, the subject matter of which is incorporated herein by reference in its entirety.

### TECHNICAL FIELD

The described embodiments relate to metrology systems and methods, and more particularly to methods and systems for improved measurement of large dimension structures fabricated by semiconductor manufacturing processes.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor substrate. Additional examples of semiconductor fabrication processes include, but are not limited to, chemical-mechanical polishing, etch, deposition, and ion implantation. Multiple semiconductor devices may be fabricated on a single semiconductor substrate and then separated into individual semiconductor devices.

Metrology processes are used at various steps during a semiconductor manufacturing process to detect defects on substrates to promote higher yield. Optical metrology techniques offer the potential for high throughput without the risk of sample destruction. A number of optical metrology based techniques including scatterometry, ellipsometry, and reflectometry implementations and associated analysis algorithms are commonly used to characterize critical dimensions, film thicknesses, composition, overlay and other parameters of nanoscale structures.

Various optical and mechanical structures are readily fabricated using manufacturing processes developed for the manufacture of semiconductor devices, e.g., lithography, etch, deposition, etc. In some examples, micro-spiral structures with horology applications, piezoelectric Micro-Electro-Mechanical Systems (MEMS) structures with energy harvesting applications, MEMS inductor device structures, etc., are fabricated by well-developed semiconductor process technology, such as CMOS processing techniques and equipment. The ability to leverage semiconductor manufacturing technology in the production of mechanical and optical structures enables low cost production at a massive scale.

In one example, it is proposed to employ silicon with a hard oxide outer layer fabricated in the shape of a hairspring, a.k.a., balance spring, or other movement components of a timekeeping mechanism. Silicon with a hard oxide outer layer provides thermal compensating properties that are desirable in timekeeping applications. In particular, the hardness and partial elasticity of silicon make it an ideal material candidate for balance springs. Furthermore, it has been demonstrated that silicon can be shaped in the form of a flat spiral more accurately and easily using semiconductor device fabrication equipment compared to coiling wire alloy into a spiral spring shape using standard wire forming processes.

A critical performance characteristic of a balance spring is isochronism. Isochronism is the ability of an oscillator to maintain the same oscillatory period, independent of its amplitude of motion. Ideally, each oscillatory cycle of a balance spring should take the same amount of time regardless of how large or small the amplitude of motion along an arc shaped trajectory. As the main spring of a mechanical timekeeping device unwinds, less and less torque is delivered to the escapement mechanism. This causes the balance spring to oscillate at decreasing amplitude. Isochronal balance springs are highly desirable, as the balance spring retains the same vibrational period despite decreasing vibrational amplitude.

FIG. 1 is a perspective view of a silicon based mechanical hairspring 10 suitable for application in a mechanical timekeeping device. The hairspring 10 is concentric with a spiral geometry. A thin layer of Silicon Dioxide is deposited on the Silicon hairspring structure.

It is critical to maintain a concentric spiral shape to achieve the desired isochronous performance, and thus provide reliable and stable time regulation. If there is a concentricity deformation of the hairspring structure, adjacent turnings may collide and damage each other causing non-isochronous performance. In some examples, adjacent turnings are within 60 to 80 micrometers from one another, and the height of the hairspring structure is in a range from 150 to 200 micrometers.

In general, it is critical to control the height, sidewall angle, the Critical Dimension (CD), and spacing of spiral turnings. In particular, a metrology solution is required to measure concentricity and the shape of the outermost spiral turning to enable control of the manufacturing process and avoid excess complexity and cost in a mass production scenario.

Silicon based structural elements typically include structures having a relatively large spatial periodicity compared to semiconductor memory or logic structures, or no spatial periodicity at all, as is the case with spiral-shaped structures. These characteristics create challenges for film and CD measurements using scatterometry based techniques. For example, the ability to measure the critical dimensions that define the shape of each turning of a hairspring structure is critical to achieve desired timekeeping performance and device yield. Similarly, the ability to measure the critical dimensions that define the shape of piezoelectric MEMS structures with energy harvesting applications, MEMS inductor device structures, etc., is critical to achieve desired electromechanical performance and device yield.

The measurement of relatively large dimension structures using conventional scatterometry based metrology systems is inadequate due to a number of physical limitations. For example, a structure having a spiral geometry, such as a balance spring, is not periodic, whereas a scatterometry based metrology system requires periodic targets to achieve accurate measurement results. In another example, conventional, scatterometry based metrology systems employ a measurement spot size of approximately 50 micrometers, whereas the width of a single turning and the space between turnings of a typical balance spring is approximately 100 micrometers. Thus, the measurement spot size of conventional, scatterometry based metrology systems is too small to accurately measure relatively large dimension structures, such as a balance spring employed in typical timepieces. More specifically, the low grating density relative to the measurement spot size results in extremely low measurement sensitivity.

In another example, the depth of the trench feature between adjacent turnings of a typical balance spring is significantly greater than 100 micrometers, whereas the sensitivity of scatterometry based metrology systems decreases significantly at depths greater than approximately 100 micrometers. Although longer integration times can be employed to counteract some loss of measurement sensitivity, the resulting long time to solution makes this approach undesirable.

Existing metrology tools manufactured by KLA Corporation include the SpectraShape™ SS10k, SS11K, and S12k tools focused on critical dimension and shape metrology, and SpectraFilm™ F1-F20 tools focused on film metrology. However, currently, there is no optical critical dimensions solution for devices with pitches over 50 micrometers and trench depth over 100 micrometers.

In summary, manufacturers of large scale structures require metrology tools capable of high throughput, non-destructive measurement of devices manufactured using conventional semiconductor device fabrication processes. The structural features of semiconductor based balance spring devices impose difficult requirements on optical metrology systems. Optical metrology systems must meet high precision and accuracy requirements for relatively large scale structures at high throughput to remain cost effective. Thus, improved metrology systems and methods to overcome these limitations are desired.

### SUMMARY

Methods and systems for performing accurate and robust scatterometry based measurements of relatively large dimension structures fabricated using semiconductor fabrication processes are presented herein. In some examples, relatively large dimension structures include spiral-shaped features that are not periodic, and thus are not traditionally amenable to measurement by scatterometry based metrology. Examples of relatively large dimension structures fabricated using semiconductor fabrication processes include, but are not limited to, spiral-shaped mechanical spring structures for mechanical timekeeping devices, piezoelectric MicroElectroMechanical Systems (MEMS) energy harvesting devices, MEMS inductor devices, etc.

In one aspect, one or more semiconductor fabrication processes, e.g., photolithography, etch, deposition, etc., are employed to fabricate one or more relatively large dimension device structures on a specimen along with one or more proxy metrology targets fabricated on the same specimen. In some examples, each of the one or more proxy metrology targets are spatially periodic and include an array of nominally identical curved segments characterized by a radius of curvature. The radius of curvature associated with each of the plurality of proxy metrology targets corresponds to the radius of curvature of each of the plurality of turnings of a spiral-shaped device structure.

In preferred embodiments, the size of each proxy metrology target is larger than the measurement spot size. In this manner, only the periodic features of the proxy metrology target are interrogated by the measurement spot. In general, the proxy metrology targets are designed to be amenable to measurement by a scatterometry based metrology system, and thus, by proxy, enable monitor and control of the fabrication of the corresponding large dimension device structures.

In a further aspect, the film stack associated with each of the proxy metrology targets is the same as the film stack associated with each of the device structures.

In another further aspect, the line/space ratio of the array of nominally identical curved segments of each of the plurality of proxy metrology targets is the same as a line/space ratio of the plurality of turnings of each of the plurality of device structures.

In another further aspect, the pitch of the array of nominally identical curved segments of each of the plurality of proxy metrology targets is less than a pitch of plurality of turnings of each of the plurality of device structures. In general, the pitch of the proxy metrology targets is selected to maximize sensitivity to measurement by the scatterometry based measurement tool, e.g., less than half the size of the measurement spot of the scatterometry based measurement tool, and maximize correlation to the corresponding device structure.

In another further aspect, the height associated with each of the proxy metrology targets is the same for all of the proxy metrology targets. However, the height, H, associated with the proxy metrology targets is significantly less than the height of the corresponding device structure.

In general, the set of scribe line, proxy metrology targets should be fabricated in accordance with the same fabrication processes employed to fabricate the corresponding device structures to maximize correlation, while shrinking feature sizes to maximize measurement sensitivity by the scatterometry based metrology tool.

In some embodiments, the methods and systems for spectroscopic metrology described herein are applied to the measurement of relatively large dimension structures, and in particular, metrology of large dimension, spiral-shaped structures.

In one aspect, a scatterometry based measurement system is employed to estimate a value of a parameter of interest characterizing a portion of the continuous, spiral-shaped structural feature associated with one of the plurality of device structures based on measurements of a corresponding proxy metrology target.

In one further aspect, measured values of one or more parameters of interest characterizing a proxy structure are mapped to values of one or more parameters of interest characterizing a device structure corresponding to the proxy structure.

In a further aspect, a trained mapping model is trained based on a fit between reference values of a parameter of interest characterizing the proxy structure and reference values of the corresponding parameter of interest characterizing the corresponding device structure.

In another further aspect, a machine learning based measurement model is trained to estimate values of one or more parameters of interest characterizing a device structure based on measurements of a proxy metrology target corresponding to the device structure.

In another further aspect, a trained ML, proxy based measurement model is trained based on a fit between reference values of a parameter of interest characterizing the device structure and raw measurement data associated with measurements of proxy metrology targets corresponding to the parameter of interest characterizing the device structure.

In another aspect, a scatterometry based measurement system is employed to estimate a value of a parameter of interest characterizing a portion of the continuous, spiral-shaped structural feature associated with one of the plurality of device structures based on measurements of the device structure.

In some embodiments, raw measurement data associated with measurements of a real structure are transformed to measurement data associated with measurements of a proxy metrology target corresponding to the real structure. In turn, measured values of one or more parameters of interest characterizing the proxy structure are mapped to values of one or more parameters of interest characterizing the real structure corresponding to the proxy structure.

In another further aspect, a real to proxy measurement signal transformation model is trained based on DOE measurement signals associated with a measurement of the proxy structure and DOE measurement signals associated with the corresponding device structure. In some embodiments, DOE wafers employed to extract measurement data for training are designed to include a range of process variations to ensure robustness to future process changes. Furthermore, in some embodiments DOE measurement data is collected by multiple similarly configured metrology tools to ensure robustness to tool variations, and thus improve tool stability and matching.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 depicts an image of a perspective view of a silicon based hairspring structure fabricated on a semiconductor substrate.

FIG. 2 depicts an illustration of a top view of the silicon based hairspring structure depicted in FIG. 1.

FIG. 3 is a diagram illustrative of a semiconductor wafer including relatively large scale device structures and periodic proxy metrology targets corresponding to the relatively large scale device structures in at least one novel aspect.

FIG. 4 is a simplified diagram illustrative of a perspective view of a proxy metrology target fabricated on the wafer depicted in FIG. 3.

FIG. 5 depicts an exemplary, metrology system 100 for performing optical measurements of relatively large dimension structures fabricated on semiconductor substrates.

FIG. 6 depicts a diagram illustrative of a proxy based measurement engine 160 in one embodiment.

FIG. 7 depicts a diagram illustrative of a proxy parameter of interest (POI) to real POI map training engine 180 in one embodiments.

FIG. 8 depicts a diagram illustrative of a proxy based measurement engine 190 in one embodiment.

FIG. 9 depicts a diagram illustrative of a real to proxy measurement signal transformation training engine 200 in one embodiment.

FIG. 10 depicts a diagram illustrative of a machine learning (ML), proxy based measurement engine 210 in one embodiment.

FIG. 11 depicts a diagram illustrative of a ML, proxy based measurement model training engine 220 in one embodiment.

FIG. 12 is plot illustrating a linear function that provides a best fit between each pair of reference values of a parameter of interest characterizing a proxy metrology target, ^{PROXY}POI, and corresponding real structure, ^{REAL}POI.

FIG. 13 illustrates a method 300 of performing optical measurements of relatively large dimension structures fabricated on semiconductor substrates in at least one novel aspect.

### DETAILED DESCRIPTION

Reference will now be made in detail to background examples and some embodiments of the invention, examples of which are illustrated in the accompanying drawings.

Methods and systems for performing accurate and robust scatterometry based measurements of relatively large dimension structures fabricated using semiconductor fabrication processes are presented herein. Relatively large dimension structures include structures having critical dimension feature sizes larger than 50 micrometers, depth feature sizes larger than 100 micrometers, or both. In some examples, relatively large dimension structures include spiral-shaped features that are not periodic, and thus are not traditionally amenable to measurement by scatterometry based metrology. Examples of relatively large dimension structures fabricated using semiconductor fabrication processes include, but are not limited to, spiral-shaped mechanical spring structures for mechanical timekeeping devices, piezoelectric MicroElectroMechanical Systems (MEMS) energy harvesting devices, MEMS inductor devices, etc. In general, new metrology applications, use cases, and industries are enabled by extending the range of pitch and trench depth of structures measured by scatterometry based metrology.

A scatterometry based measurement system estimates values of one or more parameters of interest characterizing relatively large structures including, but not limited to, the geometry of each turning of a spiral-shaped coil width, the geometry of the outside turning of a spiral-shaped coil, the oxide thickness deposited on a spiral-shaped coil, etc. The parameters of interest include, but are not limited to, parameters characterizing geometric or material characteristics of relatively large structures, such as critical dimensions, height, sidewall angle, film thickness, etc.

In one aspect, one or more semiconductor fabrication processes, e.g., photolithography, etch, deposition, etc., are employed to fabricate one or more relatively large dimension device structures on a specimen, e.g., a semiconductor wafer, along with one or more proxy metrology targets fabricated on the same specimen. In some embodiments, each of the one or more relatively large dimension device structures includes a continuous, spiral-shaped structural feature having a plurality of turnings around a center point of the device structure. The relatively large dimension device structures and associated proxy metrology targets are fabricated on a substrate using semiconductor fabrication processes. The structures and targets include one or more semiconductor materials, one or more metallic materials, one or more dielectric materials, or any combination thereof. In some examples, the one or more relatively large dimension devices are characterized by critical dimensions on the order of 80 micrometers, trench depth on the order of 150 micrometers, and pitch on the order of 100 micrometers, which are all beyond currently supported ranges of scatterometry based metrology systems.

Each of the one or more proxy metrology targets are spatially periodic and include an array of nominally identical curved segments characterized by a radius of curvature. The radius of curvature associated with each of the plurality of proxy metrology targets corresponds to the radius of curvature of each of the plurality of turnings of the device structure. The proxy metrology targets are fabricated on the same specimen as the relatively large dimension device structures. In some examples, the proxy metrology targets are fabricated in the scribe lines of a semiconductor substrate. In preferred embodiments, the size of each proxy metrology target is larger than the measurement spot size. In this manner, only the periodic features of the proxy metrology target are interrogated by the measurement spot. In general, the proxy metrology targets are designed to be amenable to measurement by a scatterometry based metrology system, and thus, by proxy, enable monitor and control of the fabrication of the corresponding large dimension device structures.

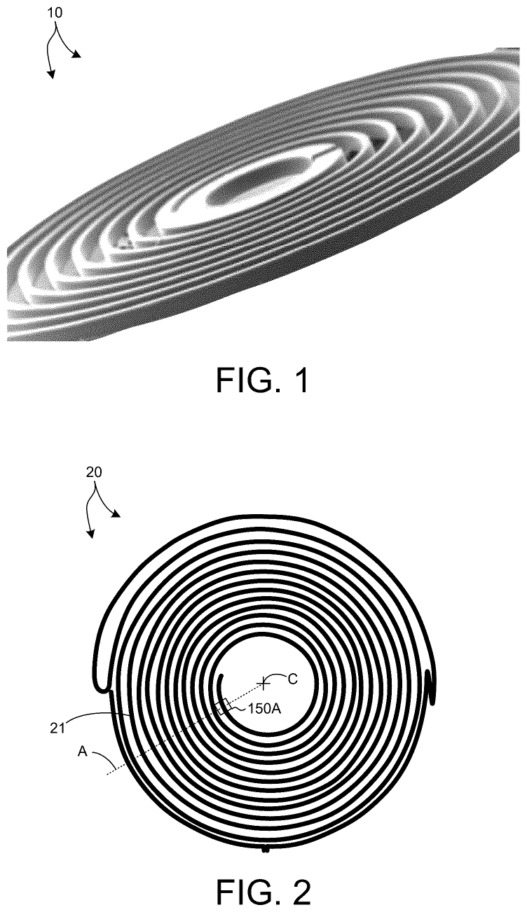

FIG. 2 is diagram 20 illustrative of a top view of the silicon based mechanical hairspring depicted in FIG. 1. As depicted in FIG. 2, the silicon based mechanical hairspring includes a continuous, spiral-shaped structural feature 21 having a plurality of turnings around a center point, C, of the device structure. Axis, A, extends from center point, C, beyond the perimeter of the hairspring device. Axis, A, intersects each turning of the continuous, spiral-shaped structural feature 21, i.e., 13 distinct turnings intersect axis, A. At the intersection with axis, A, each turning has a different radius of curvature, i.e., circular radius that approximates the curvature at the intersection of each turning with axis, A.

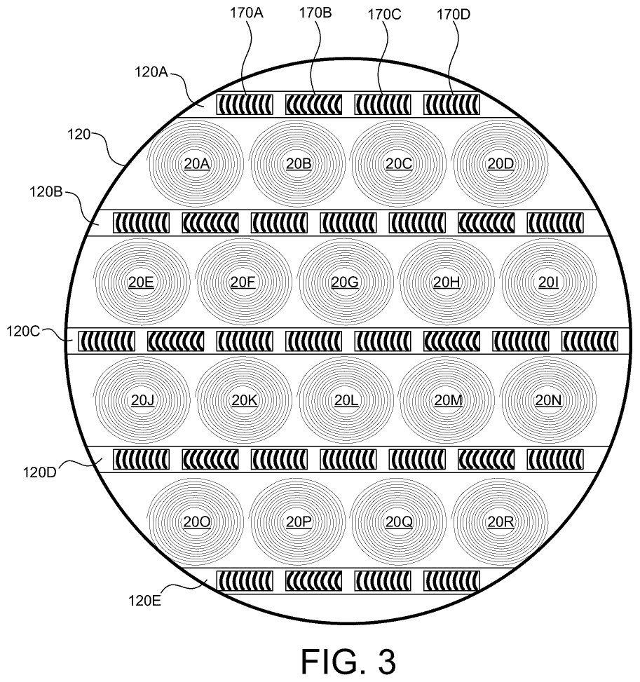

FIG. 3 is a diagram illustrative of a semiconductor wafer including relatively large scale device structures and periodic proxy metrology targets corresponding to the relatively large scale device structures in at least one novel aspect. In one aspect, wafer 120 includes 18 instances of hairspring 20 fabricated on wafer 120, i.e., silicon based mechanical hairspring structures 20A-R. In addition, wafer 120 includes five scribe lines, i.e., scribe lines 120A-E. In the scribe lines 120A-E, different proxy metrology targets are fabricated, e.g., proxy metrology targets 170A-D fabricated in scribe line 120A. The size and number of device structures and the size and number of proxy metrology targets depicted in FIG. 3 are selected for illustrative purposes only. In actual implementation, it is expected that the size and number of device structures and the size and number of proxy metrology targets will be quite different.

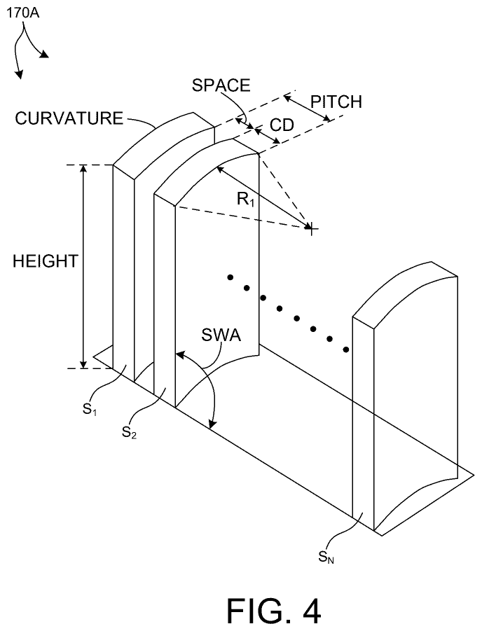

FIG. 4 is a simplified diagram illustrative of a perspective view of proxy metrology target 170A fabricated on wafer 120 depicted in FIG. 3. As depicted in FIG. 4, proxy metrology target 170A includes an array of nominally identical curved segments, S₁. . . S_{N}. Each curved segment is characterized by the same radius of curvature, R₁, height, H, pitch, P, critical dimension, CD, and space between each segment, i.e., the difference between the pitch and the CD. As depicted in FIG. 3, the radius of curvature, R₁, associated with proxy metrology target 170A is the same as the radius of curvature, R₁, associated with the first turning of any of hairsprings 20A-R, i.e., the intersection of the continuous, spiral-shaped structural feature 21 with axis, A, at the location closest to center point, C. Thus, proxy metrology target 170A corresponds to a measurement spot 150A depicted in FIG. 2. Similarly, the radius of curvature, R₂, associated with proxy metrology target 170B is the same as the radius of curvature, R₂, associated with the second turning of any of hairsprings 20A-R, i.e., the intersection of the continuous, spiral-shaped structural feature 21 with axis, A, at the location second closest to center point, C. In this example, wafer 120 includes thirteen different proxy metrology targets, each having a different radius of curvature that corresponds with a different radius of curvature associated with the thirteen different turnings intersecting axis, A.

In a further aspect, the film stack associated with each of the proxy metrology targets is the same as the film stack associated with each of the device structures 20A-R.

In another further aspect, the line/space ratio of the array of nominally identical curved segments of each of the plurality of proxy metrology targets is the same as a line/space ratio of the plurality of turnings of each of the plurality of device structures. In one example, CD of each silicon post segment of each of the proxy metrology targets is 10 micrometers, and the space between adjacent silicon post segments of each of the proxy metrology targets is also 10 micrometers. Thus, the line/space ratio associated with each of the proxy metrology targets is one. Similarly, the CD, e.g., width, of each turning of the continuous, spiral-shaped structural feature 21 of each of the device structures is 80 micrometers, and the space between adjacent turnings of the continuous, spiral-shaped structural feature 21 of each of the device structures is also 80 micrometers. Thus, the line/space ratio associated with each of the device structures is one.

In another further aspect, the pitch of the array of nominally identical curved segments of each of the plurality of proxy metrology targets is less than a pitch of plurality of turnings of each of the plurality of device structures. In one example, the pitch of each proxy metrology target is 20 micrometers, and the pitch of each corresponding device structure is 160 micrometers. In some embodiments, the pitch of the proxy metrology targets is designed to be in a range from 10 to 30 micrometers. However, in general, the pitch of the proxy metrology targets is selected to maximize sensitivity to measurement by the scatterometry based measurement tool, e.g., less than half the size of the measurement spot of the scatterometry based measurement tool, and maximize correlation to the corresponding device structure.

In another further aspect, the height associated with each of the proxy metrology targets is the same for all of the proxy metrology targets associated with hairsprings 20A-R. However, the height, H, associated with the proxy metrology targets is significantly less than the height of the turnings of hairsprings 20A-R. In one example, the height of hairsprings 20A-R is 150 micrometers, but the height, H, of the corresponding proxy metrology targets is significantly less than 100 micrometers due to the loading effect in the etch process.

In general, the set of scribe line, proxy metrology targets should be fabricated in accordance with the same fabrication processes employed to fabricate the corresponding device structures to maximize correlation, while shrinking feature sizes to maximize measurement sensitivity by the scatterometry based metrology tool. In some examples, proxy metrology targets are designed and simulated by AcuShape software available from KLA Corporation, USA.

Although, in the aforementioned example, a different proxy metrology target is associated with each turning of the continuous, spiral-shaped feature 21 of hairspring 20. However, in general, any number of different proxy metrology targets may be employed to characterize the geometric and material characteristics of the corresponding device structure.

In a further aspect, a scatterometry based measurement system is configured with a relatively small illumination Numerical Aperture (NA), e.g., less than 0.10, and a relatively small collection NA, e.g., less than 0.10, to increase the measurement spot size. In some examples, the measurement spot is characterized by a dimension along a direction of maximum extent of less than 50 micrometers. However, in some examples, the measurement spot is characterized by a dimension along a direction of maximum extent of at least 50 micrometers.

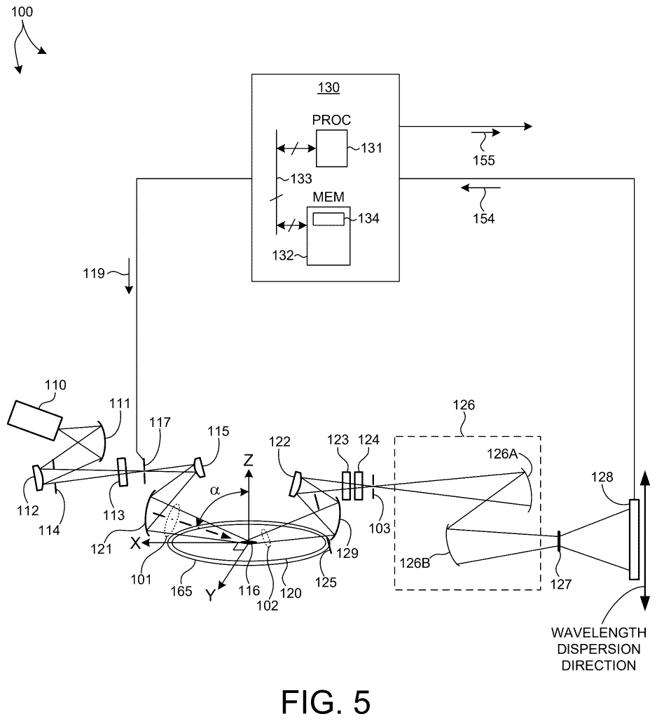

FIG. 5 depicts an exemplary, metrology system 100 for performing broadband spectroscopic measurements of relatively large dimension structures fabricated on semiconductor substrates, e.g., the hairspring structures 20A-R fabricated on wafer 120 as depicted in FIG. 3. As depicted in FIG. 5, metrology system 100 is configured as an oblique incidence, broadband spectroscopic ellipsometer. However, in general, metrology system 100 may also include additional spectroscopic ellipsometers, a spectroscopic reflectometer, angle-resolved reflectometer, scatterometer, or any combination thereof.

Metrology system 100 includes an illumination source 110 that generates a beam of illumination light 101 incident on substrate 120. Illumination source 110 includes one or more illumination sources that emit illumination light including wavelengths in a range from 120 nanometers to 2,500 nanometers. In some embodiments, illumination source 110 is a combined illumination source that emits illumination light in the ultraviolet, visible, and infrared spectra, including ultraviolet wavelengths down to 120 nanometers and infrared wavelengths greater than two micrometers, e.g., illumination wavelengths ranging from 120 nanometers to 2,500 nanometers. In some other embodiments, illumination source 110 is a combined illumination source that emits illumination light including wavelengths in a range from 120 nanometers to 7,000 nanometers.

In general, combined illumination source 110 includes a combination of a plurality of broadband or discrete wavelength light sources. The light generated by combined illumination source 110 includes a continuous spectrum or parts of a continuous spectrum, from ultraviolet to infrared (e.g., vacuum ultraviolet to long infrared). In general, combined illumination light source 110 may include a supercontinuum laser source, an infrared helium-neon laser source, a silicon carbide globar light source, a tungsten halogen light source, one or more infrared LEDs, one or more infrared lasers or any other suitable infrared light source generating wavelengths greater than two micrometers, and an arc lamp (e.g., a Xenon arc lamp), a deuterium lamp, a LSP light source, or any other suitable light source generating wavelengths less than two micrometers including visible and ultraviolet wavelengths.

As depicted in FIG. 5, metrology system 100 includes an illumination optics subsystem configured to direct illumination light 101 to one or more structures formed on substrate 120. The illumination subsystem may include any type and arrangement of optical filter(s), polarizing component, field stop, pupil stop, etc., known in the art of spectroscopic metrology. As depicted in FIG. 5, the illumination subsystem includes light source 110, beam shaping optics 111, 112, 115, and 121, polarizing component 113, and pupil stop 114. As depicted, in FIG. 5, the beam of illumination light 101 is reflected from beam shaping optics 111, 112, 115, and 121 and passes through illumination pupil stop 114, polarizing component 113, and illumination field stop 117 as the beam propagates from the illumination source 110 to substrate 120. Beam 101 illuminates a portion of substrate 120 over a measurement spot 116. As depicted in FIG. 5, beam shaping optics 111, 112, 115, and 121, include one or more optical elements having reflective focusing power.

In the embodiment depicted in FIG. 5, pupil stop 114 controls the numerical aperture (NA) of the illumination subsystem and may include any suitable commercially available aperture stop. In some embodiments, the illumination subsystem is configured to direct illumination light 101 with an illumination Numerical Aperture (NA) of less than 0.10 to substrate 120. In addition, beam shaping optics 115 and 121 control the image demagnification from illumination field stop 117 to measurement spot 116, i.e., project an image of the illumination field stop 117 to measurement spot 116 that is smaller by a demagnification factor. Note that the dimensions of measurement spot 116 across substrate 120 are not smaller than the dimensions of the illumination field stop 117 by the demagnification factor because substrate 120 is not oriented perpendicular to the illumination beam path at the point of incidence of the illumination beam 101 onto substrate 120. In some embodiments, illumination light 101 is incident at optically transparent substrate 120 at an angle of incidence, α, at or near 65 degrees from normal incidence. In some embodiments, the dimension of the measurement spot 116 along a direction of maximum extent is less than 50 micrometers.

In addition, the illumination optics subsystem may include filters, masks, apodizers, etc. For example, the illumination subsystem may include one or more optical filters (not shown). The optical filters are employed to control light level, spectral output, or both, from the illumination subsystem. In some examples, one or more multi-zone filters are employed as optical filters.

In some examples, noise and polarization optimization are performed to improve the performance of illumination source 110. In some examples, depolarization is achieved by use of multimode fibers, a Hanle depolarizer, or an integration sphere. In some examples, the illumination source etendue is optimized by use of light guides, fibers, and other optical elements (e.g., lenses, curved mirrors, apodizers, etc.). In some examples, source coherence or coherence effects are mitigated by coherence breaking techniques, or are otherwise accounted for by modeling and simulation.

Polarizing component 113 generates the desired polarization state exiting the illumination subsystem. In some embodiments, the polarizing component includes a polarizer, a compensator, or both, and may include any suitable commercially available polarizing component. The polarizer, compensator, or both, can be fixed, rotatable to different fixed positions, or continuously rotatable. Although the illumination subsystem depicted in FIG. 5 includes one polarizing component, the illumination subsystem may include more than one polarizing component. In some embodiments, a polarizer of polarizing component 113 is a Magnesium Fluoride Rochon polarizer. In some embodiments, a compensator of polarizing component 113 includes a quartz waveplate, a Magnesium Fluoride waveplate, a Calcium Fluoride K-prism, a Calcium Fluoride double Fresnel rhomb, or any combination thereof. In some embodiments, a compensator of polarizing component 113 includes one or more waveplates. In some of these embodiments, a first waveplate includes a desired retardation over a first wavelength range and a second waveplate includes a desired retardation over a second wavelength range, etc.

Metrology system 100 also includes a collection optics subsystem configured to collect light generated by the interaction between the measured structures and the incident illumination beam 101 and focus the collected light at or near a dispersive element, e.g., a spectrometer slit, of a spectrometer. The collection optics subsystem may include any type and arrangement of optical filter(s), polarizing component, collection field stop, collection pupil stop, etc., known in the art of spectroscopic metrology. In general, a collection optics subsystem includes a field stop, a pupil mask, and one or more optical elements having focusing power.

As depicted in FIG. 5, a beam of collected light 102 is collected from measurement spot 116 by a collection optics subsystem. As the beam of collection light 102 propagates from substrate 120 to dispersive element 127 of the spectrometer, collected light 102 is reflected from beam shaping optics 129 and 122 and elements of reflective collection relay optics 126, and passes through collection pupil stop 125, compensator 123, analyzer 124, and collection field stop 103 of the collection optics subsystem.

As depicted in FIG. 5, the collection optics subsystem includes a polarizing component that analyzes the polarization state of the collected light. In some embodiments, the polarizing component includes an analyzer, a compensator, or both, and may include any suitable commercially available polarizing component. The analyzer, compensator, or both, can be fixed, rotatable to different fixed positions, or continuously rotatable. The collection subsystem depicted in FIG. 1 includes a compensator 123 and an analyzer 124. In general, a collection optics subsystem may include any number of polarizing elements.

In some embodiments, compensator 123 includes a quartz waveplate, a Magnesium Fluoride waveplate, a Calcium Fluoride K-prism, a Calcium Fluoride double Fresnel rhomb, or any combination thereof. In some embodiments, compensator 123 includes one or more waveplates. In some of these embodiments, a first waveplate includes a desired retardation over a first wavelength range and a second waveplate includes a desired retardation over a second wavelength range, etc. In some embodiments, analyzer 124 is a Magnesium Fluoride Rochon analyzer.

As depicted in FIG. 5, the collection optics subsystem includes a collection pupil stop 125 disposed near a pupil of the collection optics subsystem. Collection pupil stop 125 includes one or more apertures, i.e., openings, configured to transmit collected light at one or more angles of incidence (AOIs) from optically transparent substrate 120, and block light from other AOIs. In some embodiments, collection pupil stop 125 is configured to transmit collected light with a NA less than 0.10 in the AOI direction. In some embodiments, metrology system 100 is configured with a collection NA that is the same or nearly the same as the illumination NA.

In the embodiment depicted in FIG. 5, collection field stop 103 controls the field of view of the collection optics subsystem. In some other embodiments, a spectrometer slit is employed to define the field of view of the collection optics subsystem. In a further aspect, beam shaping optics 122 and 129 control the image magnification from measurement spot 116 to detector 128, i.e., project an image of the measurement spot 116 to detector 128 that is larger by a magnification factor.

In some embodiments, a spectrometer subsystem includes the collection field stop 103, dispersive element 127, and one or more optics having reflective focusing power (not shown). The collection field stop 103 receives light from the collection optics subsystem including relay optics 126, and transmits a portion of the collected light to dispersive element 127. Dispersive element 127 disperses the light into discrete wavelengths on the active surface of detector 128.

Dispersive element 127 is typically located at or near a pupil plane of the collection optics subsystem. Relay optics 126 receives light from collection pupil stop 125 and images the light from collection pupil stop 125 to a pupil plane at or near dispersive element 127. In this manner, collection relay optics 126 functions as a pupil relay and images the collection pupil stop 125 on dispersive element 127.

In some embodiments, the optical elements of collection relay optics 126 are reflective optical elements. Reflective collection relay optics enable shorter wavelength collection light, e.g., wavelengths less than 190 nanometers. In some embodiments, reflective collection relay optics enable collection light having wavelengths in a range from 140 nanometers to 2,500 nanometers. As depicted in FIG. 5, reflective collection relay optics 126 includes reflective optical elements 126A and 126B. However, in general, reflective collection relay optics 126 may include any number of reflective optical elements. In some embodiments of metrology system 100, collection relay optics 126 are not included.

Dispersive element 127 is typically a diffraction grating or a dispersive prism. In some embodiments, dispersive element 127 includes one or more segments and each segment receives light from one or more corresponding apertures of collection pupil stop 125. In this manner, light dispersed by dispersive element 127 includes light corresponding to one or more discrete ranges of angles of incidence at the optically transparent substrate. In some embodiments, dispersive element 127 is a planar diffraction grating. In some of these embodiments, the planar diffraction grating is segmented to split the pupil into segments each corresponding to a different set of discrete ranges of angles of incidence at the optically transparent substrate. Further details regarding pupil splitting are described in U.S. Pat. No. 10,690,602 to KLA-Tencor Corporation, the content of which is incorporated herein by reference in its entirety.

As depicted in FIG. 5, detector 128 receives light collected from substrate 120 at one or more angles of incidence, multiple wavelengths, e.g., 140 nanometers to 2,500 nanometers, and one or more polarization states. In the embodiment depicted in FIG. 5, the collection optics subsystem directs light to detector 128 and the detector 128 generates output signals 154 responsive to light collected from the one or more structures illuminated by the illumination subsystem. The dispersive element 127 linearly disperses diffracted light according to wavelength along one dimension of detector 128 (i.e., the wavelength dispersion direction noted in FIG. 5). Dispersive element 127 causes a spatial separation among different wavelengths of light projected onto the surface of detector 128. In this manner, light collected from measurement spot 116 having a particular wavelength is projected onto detector 128 at a spatial location that is different from light collected from measurement spot 116 having another, different wavelength.

Metrology system 100 also includes computing system 130 configured to receive detected signals 154 and determines an estimated value of a parameter of interest 155 of the measured structure(s) based on the measured signals at a current process state of the specimen, a prior process state of the specimen, a subsequent process state of the specimen, or any combination thereof.

In general, a device structure and corresponding proxy metrology target are fabricated by a series of process steps, e.g., deposition, lithography, etch, etc. In some examples, measurement signals employed to estimate a value of a parameter of interest characterizing a proxy metrology target, corresponding device structure, or both, are derived from a single process step, e.g., a prior process step, a current process step, or a subsequent process step. In some other examples, measurement signals employed to estimate a value of a parameter of interest characterizing a proxy metrology target, corresponding proxy metrology target, or both, are derived from a measurement signals collected at multiple, different process steps. In some embodiments, measurement signals are collected at a prior process step and a subsequent process step. In some of these embodiments, measurement signals collected at different process steps are concatenated and provided as input to train models and estimate values of parameters of interest as described hereinafter. In some embodiments, differences between measurement signals collected at different process steps are calculated and provided as input to train models and estimate values of parameters of interest as described hereinafter.

In some embodiments, the methods and systems for spectroscopic metrology described herein are applied to the measurement of relatively large dimension structures, and in particular, metrology of large dimension, spiral-shaped structures. As described hereinbefore, spiral-shaped structures are not periodic in nature, and thus are not amenable to measurement using scatterometry techniques.

However, in a further aspect, a scatterometry based measurement system is employed to estimate a value of a parameter of interest characterizing a portion of the continuous, spiral-shaped structural feature associated with one of the plurality of device structures based on measurements of a corresponding proxy metrology target.

In one further aspect, measured values of one or more parameters of interest characterizing a proxy structure are mapped to values of one or more parameters of interest characterizing a device structure corresponding to the proxy structure.

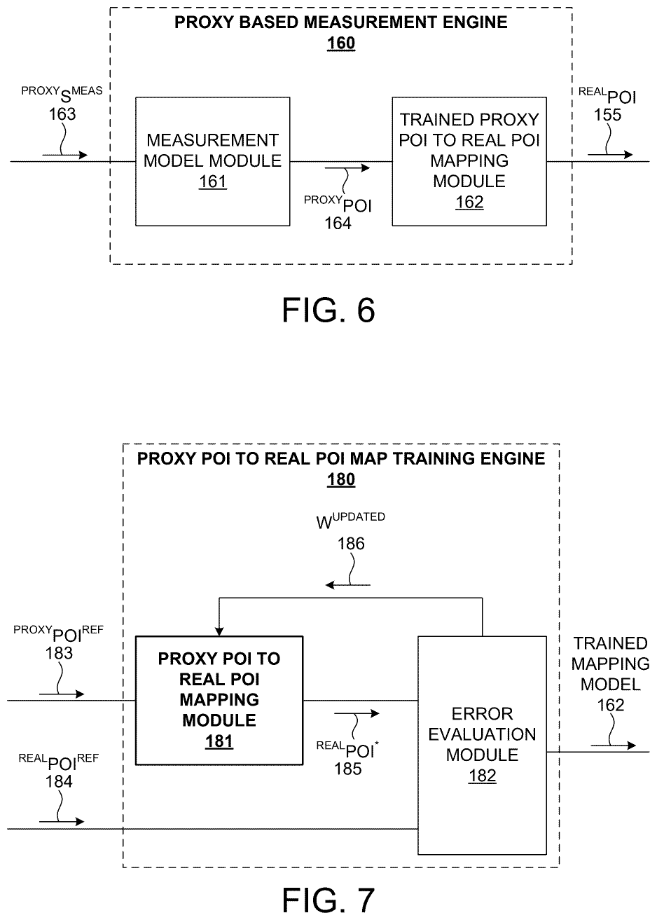

FIG. 6 depicts a diagram illustrative of a proxy based measurement engine 160 in one embodiment. In some embodiments, computing system 130 is configured as proxy based measurement engine 160. As depicted in FIG. 6, measured spectral signals, ^{PROXY}S^{MEAS} 163, e.g., measured spectral signals generated by detector 128, are received by proxy based measurement engine 160. Measured spectral signals, ^{PROXY}S^{MEAS} 163, include measurement data associated with a proxy metrology target, e.g., proxy metrology target 170A. Measured spectral signals, ^{PROXY}S^{MEAS} 163, are communicated to measurement model module 161. Measurement model module 161 includes a measurement model that operates on measured spectral signals, ^{PROXY}S^{MEAS} 163, to generate a value of a parameter of interest, e.g., CD, H, SWA, H, Roughness, etc., characterizing the proxy metrology target under measurement. Since the proxy metrology target is periodic and sized to maximize signal sensitivity, the measurement model is able to estimate the value of the parameter of interest characterizing the proxy metrology target with high accuracy.

In some embodiments, the measurement model includes a physics based measurement model. A regression analysis is performed by measurement model module 161 to estimate the value of the parameter of interest characterizing the proxy metrology target that results in a closest fit between the measured spectral signals, ^{PROXY}S^{MEAS} 163, and spectral values simulated by the physics based measurement model.

In some other embodiments, the measurement model includes a machine learning based measurement model that is trained to estimate the value of the parameter of interest characterizing the proxy metrology target based on the measured spectral signals, ^{PROXY}S^{MEAS} 163.

In some other embodiments, the measurement model includes a physics assisted, machine learning based measurement model that is trained to estimate the value of the parameter of interest characterizing the proxy metrology target based on the measured spectral signals, ^{PROXY}S^{MEAS} 163.

As depicted in FIG. 6, the estimated value of the parameter of interest, ^{PROXY}POI 164, is communicated to trained proxy POI to real POI mapping module 162. Trained proxy POI to real POI mapping module 162 includes a mathematical function, look-up table, or library, which maps the value of each parameter of interest characterizing the proxy metrology target to a corresponding value of the parameter of interest characterizing the corresponding real device structure, e.g., a hairspring. For example, trained proxy POI to real POI mapping module 162 includes a mathematical function, look-up table, or library, which maps the value of CD characterizing the proxy metrology target 170A depicted in FIG. 4 to a corresponding value of CD characterizing the first turning of the continuous spiral-shaped feature 21 depicted in FIG. 2, at location 150A. Similarly, trained proxy POI to real POI mapping module 162 includes mathematical functions, look-up tables, or libraries, which map the values of height, SWA, Roughness, Radius, etc., characterizing the proxy metrology target 170A depicted in FIG. 4 to corresponding values of height, SWA, Radius, etc., characterizing the first turning of the continuous spiral-shaped feature 21 depicted in FIG. 2, at location 150A. In some examples, the corresponding value of the parameter of interest characterizing the corresponding real device structure, ^{REAL}POI 155, is communicated from computing system 130 to a memory, e.g., memory 132.

In a further aspect, a trained mapping model is trained based on a fit between reference values of a parameter of interest characterizing the proxy structure and reference values of the corresponding parameter of interest characterizing the corresponding device structure.

FIG. 7 depicts a diagram illustrative of a proxy POI to real POI map training engine 180 in one embodiment. In some embodiments, computing system 130 is configured as a proxy POI to real POI map training engine 180. As depicted in FIG. 7, proxy POI to real POI map training engine 180 includes proxy POI to real POI mapping module 181 and error evaluation module 182. As depicted in FIG. 7, reference values of a parameter of interest characterizing a proxy metrology target, ^{PROXY}POI^{REF} 183, and reference values of the corresponding parameter of interest characterizing the corresponding device structure, ^{REAL}POI^{REF} 184, are received by proxy POI to real POI mapping module 181. In some examples, reference values are values measured by a trusted measurement system, e.g., a Transmission Electron Microscope (TEM), a Scanning Electron Microscope (SEM), an Atomic Force Microscope (AFM), etc. In other examples, reference values are values generated by a trusted simulation. In some embodiments, proxy POI to real POI mapping module 181 includes a mathematical function that maps each reference value of the parameter of interest characterizing each proxy metrology target, ^{PROXY}POI^{REF} 183, to an estimated value of the corresponding parameter of interest characterizing the corresponding device structure, ^{REAL}POI* 185.

Error evaluation module 182 computes a difference between each estimated value of the corresponding parameter of interest characterizing the corresponding device structure, ^{REAL}POI* 185, and the corresponding reference values of the corresponding parameter of interest characterizing the corresponding device structure, ^{REAL}POI^{REF} 184. If the computed residual error is equal to or less than a predetermined threshold value, error evaluation module 182 communicates the trained mapping model 162 to a memory, e.g., memory 132. If the computed residual error is greater than the predetermined threshold value, error evaluation module 182 computes updated values of the parameters of the mathematical function, W^{UPDATED} 186, to proxy POI to real POI mapping module 181. Proxy POI to real POI mapping module 181 again maps each reference value of the parameter of interest characterizing each proxy metrology target, ^{PROXY}POI^{REF} 183, to an estimated value of the corresponding parameter of interest characterizing the corresponding device structure, ^{REAL}POI* 185, based on the updated values, W^{UPDATED} 186. The regression continues in an iterative loop until the computed residual error is equal to or less than the predetermined threshold value, or a maximum allowed number of iterations is reached.

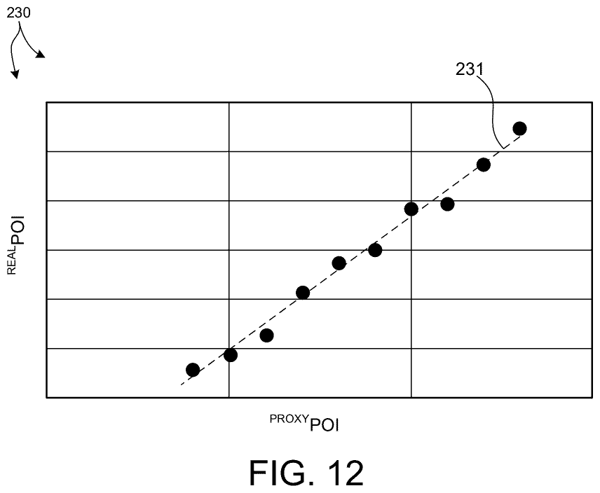

FIG. 12 is plot 230 illustrating a linear function 231 that provides a best fit between each pair of reference values of a parameter of interest characterizing a proxy metrology target, ^{PROXY}POI, and corresponding real structure, ^{REAL}POI, represented by the depicted dots.

In another aspect, a machine learning based measurement model is trained to estimate values of one or more parameters of interest characterizing a device structure based on measurements of a proxy metrology target corresponding to the device structure.

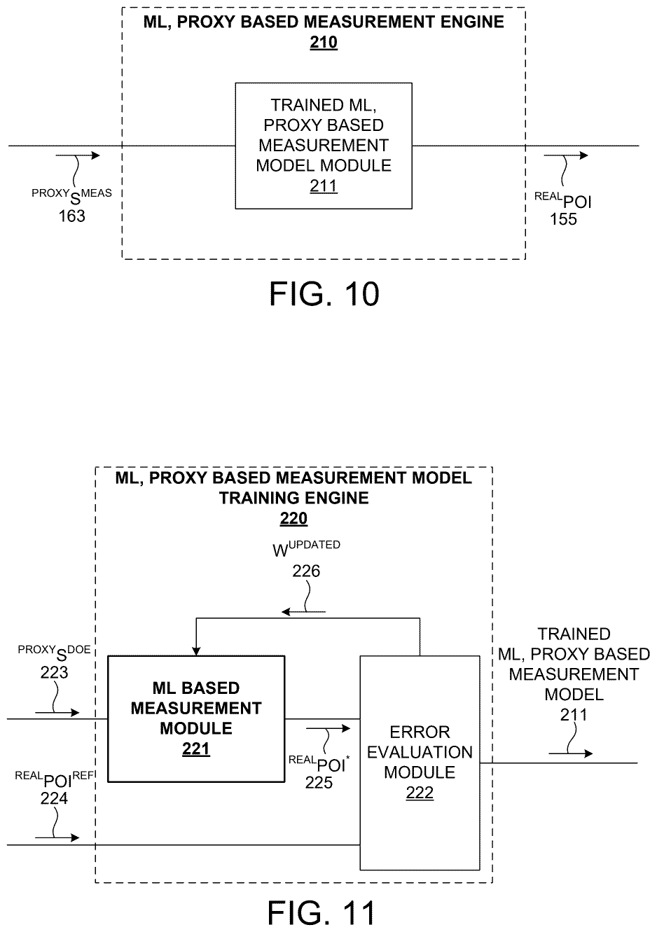

FIG. 10 depicts a diagram illustrative of a machine learning (ML), proxy based measurement engine 210 in one embodiment. In some embodiments, computing system 130 is configured as ML, proxy based measurement engine 210. As depicted in FIG. 10, measured spectral signals, ^{PROXY}S^{MEAS} 163, e.g., measured spectral signals generated by detector 128, are received by ML, proxy based measurement engine 210. Measured spectral signals, ^{PROXY}S^{MEAS} 163, include measurement data associated with a proxy metrology target, e.g., proxy metrology target 170A. Measured spectral signals, ^{PROXY}S^{MEAS} 163, are communicated to trained ML, proxy based measurement model module 211. Trained ML, proxy based measurement model module 211 includes a measurement model that operates on measured spectral signals, ^{PROXY}S^{MEAS} 163, to generate a value of a parameter of interest, e.g., CD, H, SWA, Roughness, etc., characterizing the device structure corresponding to the proxy metrology target under measurement. The measurement model is a machine learning based measurement model that is trained to estimate the value of the parameter of interest characterizing the device structure, ^{REAL}POI 155, based on the measured spectral signals, ^{PROXY}S^{MEAS} 163, collected from the corresponding proxy metrology target. In some examples, the value of the parameter of interest characterizing the device structure, ^{REAL}POI 155, is communicated from computing system 130 to a memory, e.g., memory 132.

In a further aspect, a trained ML, proxy based measurement model is trained based on a fit between reference values of a parameter of interest characterizing the device structure and raw measurement data associated with measurements of proxy metrology targets corresponding to the parameter of interest characterizing the device structure.

FIG. 11 depicts a diagram illustrative of a ML, proxy based measurement model training engine 220 in one embodiment. In some embodiments, computing system 130 is configured as a ML, proxy based measurement model training engine 220. As depicted in FIG. 11, ML, proxy based measurement model training engine 220 includes ML based measurement module 221 and error evaluation module 222. As depicted in FIG. 11, Design Of Experiments (DOE) measurement signals associated with measurements of many proxy metrology targets, ^{PROXY}S^{DOE} 223, are received by ML based measurement module 221. ML based measurement module 221 includes a ML model, e.g., neural network model, that transforms each set of measurements of each proxy metrology target to an estimated value of each parameter of interest, ^{REAL}POI* 225, characterizing the corresponding device structure.

Error evaluation module 222 receives reference values of each parameter of interest characterizing each device structure, ^{REAL}POI^{REF} 224. Each reference value of each parameter of interest characterizing each device structure corresponds to a proxy metrology target included in corresponding data set, ^{PROXY}S^{DOE} 223. In some examples, reference values are values measured by a trusted measurement system, e.g., a Transmission Electron Microscope (TEM), a Scanning Electron Microscope (SEM), an Atomic Force Microscope (AFM), etc. In other examples, reference values are values generated by a trusted simulation.

Error evaluation module 182 computes a difference between each estimated value of each parameter of interest characterizing the device structure, ^{REAL}POI* 225, and the reference values of the corresponding parameter of interest characterizing the corresponding device structure, ^{REAL}POI^{REF} 224. If the computed residual error is equal to or less than a predetermined threshold value, error evaluation module 222 communicates the trained ML, proxy based measurement model 211 to a memory, e.g., memory 132. If the computed residual error is greater than the predetermined threshold value, error evaluation module 222 computes updated values of the weighting parameters of the ML model, W^{UPDATED} 226, to ML based measurement module 221. ML based measurement model again transforms each set of DOE measurement signals, ^{PROXY}S^{DOE} 223, to an estimated value of the corresponding parameter of interest characterizing the corresponding device structure, ^{REAL}POI* 225, based on the updated values, W^{UPDATED} 226. The regression continues in an iterative loop until the computed residual error is equal to or less than the predetermined threshold value, or a maximum allowed number of iterations is reached.

In another aspect, a scatterometry based measurement system is employed to estimate a value of a parameter of interest characterizing a portion of the continuous, spiral-shaped structural feature associated with one of the plurality of device structures based on measurements of the device structure.

In some embodiments, raw measurement data associated with measurements of a real structure are transformed to measurement data associated with measurements of a proxy metrology target corresponding to the real structure. In turn, measured values of one or more parameters of interest characterizing the proxy structure are mapped to values of one or more parameters of interest characterizing the real structure corresponding to the proxy structure.

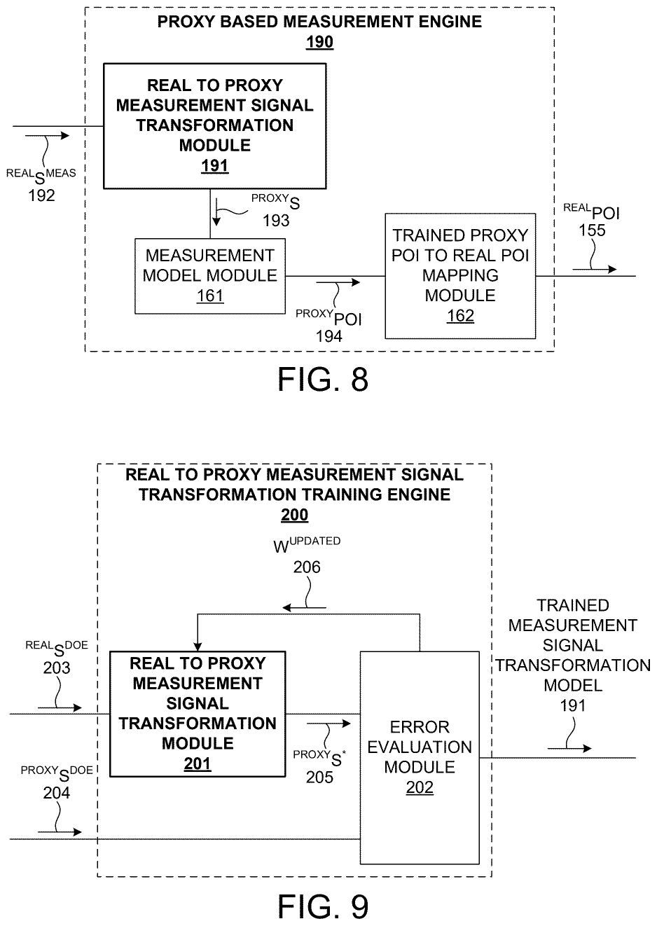

FIG. 8 depicts a diagram illustrative of a proxy based measurement engine 190 in another embodiment. In some embodiments, computing system 130 is configured as proxy based measurement engine 190. As depicted in FIG. 8, measured spectral signals, ^{REAL}S^{MEAS} 192, e.g., measured spectral signals generated by detector 128, are received by proxy based measurement engine 190. Measured spectral signals, ^{REAL}S^{MEAS} 192, include measurement data associated with a device structure, e.g., measurement data collected from measurement location 150 depicted in FIG. 2. Measured spectral signals, ^{REAL}S^{MEAS} 192, are communicated to real to proxy measurement signal transformation module 191. Real to proxy measurement signal transformation module 191 includes transformation model, e.g., a ML based model, that transforms the measured spectral signals, ^{REAL}S^{MEAS} 192, to estimated spectral signals, ^{PROXY}S 193, associated with a measurement of a proxy metrology target, e.g., proxy metrology target 170A, corresponding to the device structure.

The estimated spectral signals, ^{PROXY}S 193, are communicated to measurement model module 161. Measurement model module 161 includes a measurement model that operates on estimated spectral signals, ^{PROXY}S 193, to generate a value of a parameter of interest, e.g., CD, H, SWA, Roughness, etc., characterizing the proxy metrology target corresponding to the device structure under measurement. Since the proxy metrology target is periodic and sized to maximize signal sensitivity, the measurement model is able to estimate the value of the parameter of interest characterizing the proxy metrology target with high accuracy.

In some embodiments, the measurement model includes a physics based measurement model. A regression analysis is performed by measurement model module 161 to estimate the value of the parameter of interest characterizing the proxy metrology target that results in a closest fit between the estimated spectral signals, ^{PROXY}S 193, and spectral values simulated by the physics based measurement model.

In some other embodiments, the measurement model includes a machine learning based measurement model that is trained to estimate the value of the parameter of interest characterizing the proxy metrology target based on the estimated spectral signals, ^{PROXY}S 193.

As depicted in FIG. 8, the estimated value of the parameter of interest, ^{PROXY}POI 194, is communicated to trained proxy POI to real POI mapping module 162 as described with reference to FIG. 6. Trained proxy POI to real POI mapping module 162 includes a mathematical function, look-up table, or library, which maps the value of each parameter of interest characterizing the proxy metrology target to a corresponding value of the parameter of interest characterizing the corresponding real device structure, e.g., a hairspring. For example, trained proxy POI to real POI mapping module 162 includes a mathematical function, look-up table, or library, which maps the value of CD characterizing the proxy metrology target 170A depicted in FIG. 4 to a corresponding value of CD characterizing the first turning of the continuous spiral-shaped feature 21 depicted in FIG. 2, at location 150A. Similarly, trained proxy POI to real POI mapping module 162 includes mathematical functions, look-up tables, or libraries, which map the values of height, SWA, Roughness, Radius, etc., characterizing the proxy metrology target 170A depicted in FIG. 4 to corresponding values of height, SWA, Radius, etc., characterizing the first turning of the continuous spiral-shaped feature 21 depicted in FIG. 2, at location 150A. In some examples, the corresponding value of the parameter of interest characterizing the corresponding real device structure, ^{REAL}POI 155, is communicated from computing system 130 to a memory, e.g., memory 132.

In a further aspect, a real to proxy measurement signal transformation model is trained based on DOE measurement signals associated with a measurement of the proxy structure and DOE measurement signals associated with the corresponding device structure. In some embodiments, DOE wafers employed to extract measurement data for training are designed to include a range of process variations to ensure robustness to future process changes. Furthermore, in some embodiments DOE measurement data is collected by multiple similarly configured metrology tools to ensure robustness to tool variations, and thus improve tool stability and matching.

FIG. 9 depicts a diagram illustrative of a real to proxy measurement signal transformation training engine 200 in one embodiment. In some embodiments, computing system 130 is configured as a real to proxy measurement signal transformation training engine 200. As depicted in FIG. 9, real to proxy measurement signal transformation training engine 200 includes real to proxy measurement signal transformation module 201 and error evaluation module 202. As depicted in FIG. 9, measurement signals associated with a measurement of the proxy structure, ^{REAL}S^{DOE} 203, and measurement signals associated with the corresponding device structure, ^{PROXY}POI^{DOE} 204, are received by real to proxy measurement signal transformation module 201. In some examples, measurement values are actual measurement values measured by the metrology system or another instance of a similarly configured metrology system. In other examples, the measurement values are simulated values generated by a trusted simulation. In some embodiments, real to proxy measurement signal transformation module 201 includes a transformation model, e.g., a ML model, that transforms each set of measurement signals associated with a real device structure to estimated measurement signals, ^{PROXY}S* 205, associated with a proxy metrology target corresponding to the device structure, e.g., same curvature.

Error evaluation module 202 computes a difference between each set of estimated measurement signals, ^{PROXY}S* 205, associated with each proxy metrology target and the each corresponding set of DOE measurement signals, ^{PROXY}S^{DOE} 204, associated with each corresponding device structure. If the computed residual error is equal to or less than a predetermined threshold value, error evaluation module 202 communicates the trained measurement signal transformation model 191 to a memory, e.g., memory 132. If the computed residual error is greater than the predetermined threshold value, error evaluation module 202 computes updated values of the parameters of the transformation model, W^{UPDATED} 206, to real to proxy measurement signal transformation module 201. Real to proxy measurement signal transformation module 201 again transforms each set of measurement signals associated with a real device structure to estimated measurement signals, ^{PROXY}S* 205, associated with a proxy metrology target corresponding to the device structure, based on the updated values, W^{UPDATED} 206. The regression continues in an iterative loop until the computed residual error is equal to or less than the predetermined threshold value, or a maximum allowed number of iterations is reached.

In some embodiments, the ML based models described herein are implemented as neural network models. In other examples, any of the ML based models described herein may be implemented as a linear model, a non-linear model, a polynomial model, a response surface model, a support vector machines model, a decision tree model, a random forest model, a kernel regression model, a deep network model, a convolutional network model, or other types of models.

In general, corresponding device structures and proxy metrology targets are fabricated on the same wafers with the same fabrication process values and variance of critical dimensions.

In general, measured values of parameters of interest characterizing device structures, ^{REAL}POI 155 are employed to control the fabrication process, estimate device performance, or both.

As depicted in FIG. 5, metrology system 100 includes a spectral ellipsometer measurement system. However, in general, metrology system 100 may include any number of additional measurement systems, e.g., angle resolved reflectometer system, spectroscopic reflectometer system, etc. By way of non-limiting example, metrology system 100 may be configured to include a spectroscopic ellipsometer (including Mueller matrix ellipsometry), a spectroscopic reflectometer, a spectroscopic scatterometer, an overlay scatterometer, an angular resolved beam profile reflectometer, a polarization resolved beam profile reflectometer, a beam profile reflectometer, a beam profile ellipsometer, any single or multiple wavelength ellipsometer, or any combination thereof.

In general, a collection optics subsystem may direct light to more than one detector. In these embodiments, two or more detectors are each configured to detect collected light over different wavelength ranges, simultaneously.

In one example, one detector is a charge coupled device (CCD) sensitive to ultraviolet and visible light (e.g., light having wavelengths between 190 nanometers and 860 nanometers), and another detector is a photo detector array (PDA) sensitive to infrared light (e.g., light having wavelengths between 950 nanometers and 5000 nanometers). However, in general, other two dimensional detector technologies may be contemplated (e.g., a position sensitive detector (PSD), an infrared detector, a photovoltaic detector, etc.). Each detector converts the incident light into electrical signals indicative of the spectral intensity of the incident light. In some embodiments, the detection subsystem is arranged such that the collected light propagates to all detectors of metrology system 100, simultaneously. By simultaneously collecting UV and IR spectra, measurement times are reduced and all spectra are measured with the same alignment conditions. This allows wavelength errors to be corrected more easily because a common correction can be applied to all spectral data sets.

In general, dispersive element 127 may be configured to subdivide the incident light into different wavelength bands, propagate the different wavelength bands in different directions, and disperse the light of one of the wavelength bands onto one or more detectors in any suitable manner. In one example, dispersive element 127 is configured as a transmissive grating. In some other examples, dispersive element 127 includes a beam splitting element to subdivide the beam into different wavelength bands and a reflective or transmissive grating structure to disperse one of the wavelength bands onto a detector.

In some embodiments, dispersive element 127 is a reflective grating configured to diffract a subset of wavelengths of the incident light into the +/−1 diffraction order toward one detector and diffract a different subset of wavelengths of the incident light into the zero diffraction order toward another detector.

By measuring a target with infrared, visible, and ultraviolet light in a single system, precise characterization of complex three dimensional structures is enabled. In general, relatively long wavelengths penetrate deep into a structure and provide suppression of high diffraction orders when measuring structures with relatively large pitch. Relatively short wavelengths provide precise dimensional information about structures such as relatively small CD and roughness features. In some examples, longer wavelengths enable measurement of dimensional characteristics of targets with relatively rough surfaces or interfaces due to lower sensitivity of longer wavelengths to roughness. In general, measuring a target with infrared, visible, and ultraviolet light in a single system improves sensitivity to some measurement parameters and reduces correlations among parameters.

As depicted in FIG. 5, the illustrated measurement channel includes a polarizer on the illumination side and an analyzer on the collection side. However, in general, it is contemplated that any measurement channel may include, or not include, an illumination polarizer, a collection analyzer, an illumination compensator, a collection compensator, in any combination, to perform measurements of the polarized reflectivity of the sample, unpolarized reflectivity of the sample, or both.

In some embodiments, one or more measurement channels of the metrology system are configured to measure the optically transparent substrate at different azimuth angles, in addition to different ranges of wavelength and angle of incidence. In some embodiments, a metrology system including an infrared spectrometer as described herein is configured to perform measurements of the optically transparent substrate at azimuth angles of zero and ninety degrees relative to the metrology target. In some embodiments, the metrology system is configured to measure optically transparent substrate reflectivity over one or more wavelength ranges, one or more AOI ranges, and one or more azimuth angles simultaneously. In some embodiments, a metrology system utilizes one or more combined LSP & supercontinuum sources in one or more spectroscopic ellipsometers, spectroscopic reflectometers, discrete wavelength ellipsometers, rotating polarizer ellipsometers, rotating compensator ellipsometers, rotating polarizer rotating compensator ellipsometers, Mueller-matrix ellipsometers, or any combination thereof.

In the embodiment depicted in FIG. 5, computing system 130 is configured to receive signals 154 indicative of the spectral response detected by the detector subsystem. Computing system 130 is further configured to determine control signals 119 that are communicated to programmable illumination field stop 117. Programmable illumination field stop 117 receives control signals 119 and adjusts the size of the illumination aperture to achieve the desired illumination field size.

In some examples, the illumination field stop is adjusted to optimize measurement accuracy and speed as described hereinbefore. In another example, the illumination field stop is adjusted to prevent image clipping by the spectrometer slit and corresponding degradation of measurement results. In this manner, the illumination field size is adjusted such that the image of the measurement target underfills the spectrometer slit. In one example, the illumination field stop is adjusted such that the projection of the polarizer slit of the illumination optics underfills the spectrometer slit of the metrology system. In another example, the illumination field stop is adjusted such that the projection of the polarizer slit of the illumination optics overfills the spectrometer slit of the metrology system.

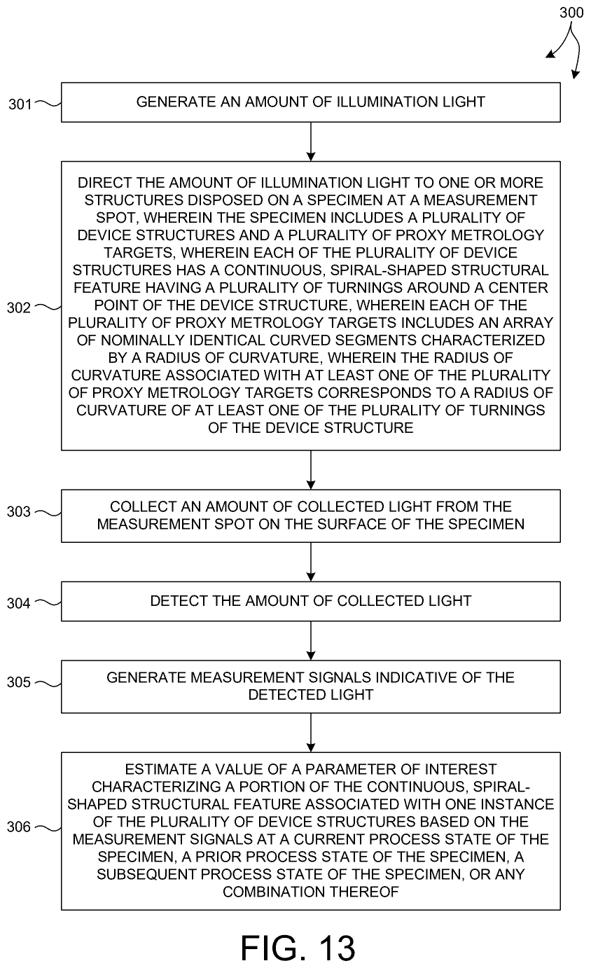

FIG. 13 illustrates a method 300 of performing spectroscopic measurements in at least one novel aspect. Method 300 is suitable for implementation by a metrology system such as metrology system 100 illustrated in FIG. 1 of the present invention. In one aspect, it is recognized that data processing blocks of method 300 may be carried out via a pre-programmed algorithm executed by one or more processors of computing system 130, or any other general purpose computing system. It is recognized herein that the particular structural aspects of metrology system 100 do not represent limitations and should be interpreted as illustrative only.

In block 301, an amount of illumination light is generated.

In block 302, the amount of illumination light is directed to one or more structures disposed on a specimen at a measurement spot. The specimen includes a plurality of device structures and a plurality of proxy metrology targets. Each of the plurality of device structures has a continuous, spiral-shaped structural feature having a plurality of turnings. Each of the plurality of proxy metrology targets includes an array of nominally identical curved segments characterized by a radius of curvature. The radius of curvature associated with at least one of the plurality of proxy metrology targets corresponds to the radius of curvature of at least one of the plurality of turnings of the device structure.

In block 303, an amount of light is collected from the measurement spot on the surface of the specimen.

In block 304, the amount of collected light is detected.

In block 305, output signals indicative of the detected light are generated.

In block 306, a value of a parameter of interest characterizing a portion of the continuous, spiral-shaped structural feature associated with one instance of the plurality of device structures is estimated based on the measurement signals at a current process state of the specimen, a prior process state of the specimen, a subsequent process state of the specimen, or any combination thereof.

In a further embodiment, system 100 includes one or more computing systems 130 employed to perform measurements of actual device structures based on measurement data collected in accordance with the methods described herein. The one or more computing systems 130 may be communicatively coupled to the spectrometer. In one aspect, the one or more computing systems 130 are configured to receive measurement data associated with measurements of the structure of the specimen under measurement.

It should be recognized that one or more steps described throughout the present disclosure may be carried out by a single computer system 130 or, alternatively, a multiple computer system 130. Moreover, different subsystems of system 100 may include a computer system suitable for carrying out at least a portion of the steps described herein. Therefore, the aforementioned description should not be interpreted as a limitation on the present invention but merely an illustration.

In addition, the computer system 130 may be communicatively coupled to the spectrometers in any manner known in the art. For example, the one or more computing systems 130 may be coupled to computing systems associated with the spectrometers. In another example, the spectrometers may be controlled directly by a single computer system coupled to computer system 130.

The computer system 130 of metrology system 100 may be configured to receive and/or acquire data or information from the subsystems of the system (e.g., spectrometers and the like) by a transmission medium that may include wireline and/or wireless portions. In this manner, the transmission medium may serve as a data link between the computer system 130 and other subsystems of system 100.

Computer system 130 of metrology system 100 may be configured to receive and/or acquire data or information (e.g., measurement results, modeling inputs, modeling results, reference measurement results, etc.) from other systems by a transmission medium that may include wireline and/or wireless portions. In this manner, the transmission medium may serve as a data link between the computer system 130 and other systems (e.g., memory on-board metrology system 100, external memory, or other external systems). For example, the computing system 130 may be configured to receive measurement data from a storage medium (i.e., memory 132 or an external memory) via a data link. For instance, spectral results obtained using the spectrometers described herein may be stored in a permanent or semi-permanent memory device (e.g., memory 132 or an external memory). In this regard, the spectral results may be imported from on-board memory or from an external memory system. Moreover, the computer system 130 may send data to other systems via a transmission medium. For instance, a measurement model or an estimated parameter value 171 determined by computer system 130 may be communicated and stored in an external memory. In this regard, measurement results may be exported to another system.

Computing system 130 may include, but is not limited to, a personal computer system, mainframe computer system, workstation, image computer, parallel processor, cloud based computing system, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In some examples, the measurement models are implemented as an element of a SpectraShape® optical critical-dimension metrology system available from KLA Corporation, Milpitas, California, USA. In this manner, the model is created and ready for use immediately after the spectra are collected by the system.

In some other examples, the measurement models are implemented off-line, for example, by a computing system implementing AcuShape® software available from KLA Corporation, Milpitas, California, USA. The resulting, trained model may be incorporated as an element of an AcuShape® library that is accessible by a metrology system performing measurements.

In another aspect, the methods and systems for spectroscopic metrology of semiconductor devices described herein are applied to the measurement of high aspect ratio (HAR) structures, large lateral dimension structures, or both.

In yet another aspect, the measurement results described herein can be used to provide active feedback to a process tool (e.g., lithography tool, etch tool, deposition tool, etc.). For example, values of measured parameters determined based on measurement methods described herein can be communicated to a lithography tool to adjust the lithography system to achieve a desired output. In a similar way etch parameters (e.g., etch time, diffusivity, etc.) or deposition parameters (e.g., time, concentration, etc.) may be included in a measurement model to provide active feedback to etch tools or deposition tools, respectively. In some example, corrections to process parameters determined based on measured device parameter values and a trained measurement model may be communicated to a lithography tool, etch tool, or deposition tool.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the metrology system 100 may be configured for measurement of patterned optically transparent substrates and/or unpatterned optically transparent substrates. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on critical dimension data.

Various embodiments are described herein for a semiconductor measurement system that may be used for measuring a specimen within any semiconductor processing tool (e.g., an inspection system or a lithography system). The term “specimen” is used herein to refer to an optically transparent substrate, a reticle, or any other sample that may be processed (e.g., printed or inspected for defects) by means known in the art.

As used herein, the term “optically transparent substrate” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, an optically transparent substrate may include only the substrate (i.e., bare optically transparent substrate). Alternatively, an optically transparent substrate may include one or more layers of different materials formed upon a substrate. One or more layers formed on a optically transparent substrate may be “patterned” or “unpatterned.” For example, a optically transparent substrate may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO2. A reticle may be disposed above a resist-covered optically transparent substrate during an exposure step of a lithography process such that the pattern on the reticle may be transferred to the resist.

One or more layers formed on a optically transparent substrate may be patterned or unpatterned. For example, a optically transparent substrate may include a plurality of dies, each having repeatable pattern features. Formation and processing of such layers of material may ultimately result in completed devices. Many different types of devices may be formed on a optically transparent substrate, and the term optically transparent substrate as used herein is intended to encompass a optically transparent substrate on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. An optical metrology system comprising:
an illumination source configured to generate an amount of illumination light;
an illumination optics subsystem configured to direct the amount of illumination light from the illumination source to one or more structures disposed on a specimen at a measurement spot, wherein the specimen includes a plurality of device structures and a plurality of proxy metrology targets, wherein each of the plurality of device structures has a continuous, spiral-shaped structural feature having a plurality of turnings, wherein each of the plurality of proxy metrology targets includes an array of nominally identical curved segments characterized by a radius of curvature, wherein the radius of curvature associated with at least one of the plurality of proxy metrology targets corresponds to a radius of curvature of at least one of the plurality of turnings of the device structure;
a collection optics subsystem configured to collect an amount of collected light from the measurement spot on the surface of the specimen;
at least one detector having a planar, two-dimensional surface sensitive to incident light, the at least one detector configured to detect the amount of collected light and generate measurement signals indicative of the detected light; and
a computing system configured to estimate a value of a parameter of interest characterizing a portion of the continuous, spiral-shaped structural feature associated with one instance of the plurality of device structures based on the measurement signals at a current process state of the specimen, a prior process state of the specimen, a subsequent process state of the specimen, or any combination thereof.

2. The metrology system of claim 1, wherein the continuous, spiral-shaped structural feature includes a semiconductor material, a metallic material, or a dielectric material.

3. The optical metrology system of claim 1, wherein the one or more structures illuminated at the measurement spot includes a proxy metrology target of the plurality of proxy metrology targets, and wherein the estimating of the value of the parameter of interest characterizing the portion of the continuous, spiral-shaped structural feature associated with the one instance of the plurality of device structures involves:
estimating a value of a parameter of interest characterizing the proxy structure based on the measurement signals provided as input to a scatterometry based measurement model;
converting the estimated value of the parameter of interest characterizing the proxy structure to the estimated value of the parameter of interest characterizing the portion of the continuous, spiral-shaped structural feature associated with the one instance of the plurality of device structures based on a trained mapping model.

4. The optical metrology system of claim 3, wherein the scatterometry based measurement model is a physics based measurement model, a trained machine-learning based measurement model, or a physics assisted, machine learning based measurement model.

5. The optical metrology system of claim 3, wherein the radius of curvature of the proxy structure is the same as the radius of curvature of the portion of the continuous, spiral-shaped structural feature associated with the one instance of the plurality of device structures.

6. The optical metrology system of claim 3, the computing system further configured to:
train the trained mapping model based on a fit between reference values of the parameter of interest characterizing the proxy structure and reference values of the parameter of interest characterizing the device structure.

7. The optical metrology system of claim 1, wherein the one or more structures illuminated at the measurement spot includes a portion of the continuous, spiral-shaped structural feature associated with the one instance of the plurality of device structures, and wherein the estimating of the value of the parameter of interest characterizing the portion of the continuous, spiral-shaped structural feature associated with the one instance of the plurality of device structures involves:
converting the measurement signals generated by the at least one detector to estimated measurement signals associated with a proxy metrology target of the plurality of proxy metrology targets having a radius of curvature that is the same as the portion of the continuous, spiral-shaped structural feature based on a measurement signal conversion model;
estimating a value of a parameter of interest characterizing the proxy metrology target based on the estimated measurement signals provided as input to a scatterometry based measurement model;
converting the estimated value of the parameter of interest characterizing the proxy metrology target to the estimated value of the parameter of interest characterizing the portion of the continuous, spiral-shaped structural feature associated with the one instance of the plurality of device structures based on a trained mapping model.

8. The optical metrology system of claim 3, the computing system further configured to:
train the measurement signal conversion model based on measurement signals associated with a measurement of the proxy structure and measurement signals associated with the corresponding device structure.

9. The optical metrology system of claim 1, wherein the one or more structures illuminated at the measurement spot includes a proxy metrology target of the plurality of proxy metrology targets, and wherein the estimating of the value of the parameter of interest characterizing the portion of the continuous, spiral-shaped structural feature associated with the one of the plurality of device structures involves providing the measurement signals as input to a trained machine-learning based measurement model.

10. The optical metrology system of claim 9, the computing system further configured to:
train the machine-learning based measurement model based on reference values of the parameter of interest characterizing the portion of the continuous, spiral-shaped structural feature associated with the one instance of the plurality of device structures and corresponding sets of measurement signals associated with a measurement of the corresponding proxy metrology targets by the optical metrology system.

11. The optical metrology system of claim 1, wherein an illumination Numerical Aperture (NA) of the illumination optics subsystem and a collection Numerical Aperture (NA) of the collection optics subsystem are less than 0.10.

12. The optical metrology system of claim 1, wherein a dimension of the measurement spot along a direction of maximum extent is less than 50 micrometers.

13. The optical metrology system of claim 1, wherein each of the proxy metrology targets is periodic.

14. The optical metrology system of claim 1, wherein each of the device structures is a hairspring.

15. The metrology system of claim 9, wherein the parameter of interest is any of a critical dimension, a height, a sidewall angle, and a pitch.

16. A semiconductor wafer comprising:
a plurality of device structures fabricated on the semiconductor wafer, each of the plurality of device structures having a continuous, spiral-shaped structural feature having a plurality of turnings; and
a plurality of proxy metrology targets fabricated on the semicondutor wafer, each of the plurality of proxy metrology targets comprising an array of nominally identical curved segments characterized by a radius of curvature, wherein the radius of curvature associated with at least one of the plurality of proxy metrology targets corresponds to a radius of curvature of at least one of the plurality of turnings of the device structure.

17. The semiconductor wafer of claim 16, wherein the film stack comprising the plurality of device structures is the same as the film stack comprising the plurality of proxy metrology targets.

18. The semiconductor wafer of claim 16, wherein a line/space ratio of the array of nominally identical curved segments of each of the plurality of proxy metrology targets is the same as a line/space ratio of the plurality of turnings of each of the plurality of device structures.

19. The semiconductor wafer of claim 16, wherein the plurality of proxy metrology targets are fabricated within a scribe line area of the semiconductor wafer.

20. The semiconductor wafer of claim 16, wherein a pitch of the array of nominally identical curved segments of each of the plurality of proxy metrology targets is less than a pitch of plurality of turnings of each of the plurality of device structures.

21. A method comprising:
generating an amount of illumination light;
directing the amount of illumination light to one or more structures disposed on a specimen at a measurement spot, wherein the specimen includes a plurality of device structures and a plurality of proxy metrology targets, wherein each of the plurality of device structures has a continuous, spiral-shaped structural feature having a plurality of turnings around a center point of the device structure, wherein each of the plurality of proxy metrology targets includes an array of nominally identical curved segments characterized by a radius of curvature, wherein the radius of curvature associated with at least one of the plurality of proxy metrology targets corresponds to a radius of curvature of at least one of the plurality of turnings of the device structure;
collecting an amount of collected light from the measurement spot on the surface of the specimen;
detecting the amount of collected light;
generating measurement signals indicative of the detected light; and
estimating a value of a parameter of interest characterizing a portion of the continuous, spiral-shaped structural feature associated with one instance of the plurality of device structures based on the measurement signals at a current process state of the specimen, a prior process state of the specimen, a subsequent process state of the specimen, or any combination thereof.

22. The method of claim 21, wherein the one or more structures illuminated at the measurement spot includes a proxy metrology target of the plurality of proxy metrology targets, and wherein the estimating of the value of the parameter of interest characterizing the portion of the continuous, spiral-shaped structural feature associated with the one instance of the plurality of device structures involves:
estimating a value of a parameter of interest characterizing the proxy structure based on the measurement signals provided as input to a scatterometry based measurement model;
converting the estimated value of the parameter of interest characterizing the proxy structure to the estimated value of the parameter of interest characterizing the portion of the continuous, spiral-shaped structural feature associated with the one instance of the plurality of device structures based on a trained mapping model.

23. The method of claim 21, wherein the one or more structures illuminated at the measurement spot includes a portion of the continuous, spiral-shaped structural feature associated with the one instance of the plurality of device structures, and wherein the estimating of the value of the parameter of interest characterizing the portion of the continuous, spiral-shaped structural feature associated with the one instance of the plurality of device structures involves:
converting the output signals generated by the at least one detector to estimated measurement signals associated with a proxy metrology target of the plurality of proxy metrology targets having a radius of curvature that is the same as the portion of the continuous, spiral-shaped structural feature based on a measurement signal conversion model;
estimating a value of a parameter of interest characterizing the proxy metrology target based on the estimated measurement signals provided as input to a scatterometry based measurement model;
converting the estimated value of the parameter of interest characterizing the proxy metrology target to the estimated value of the parameter of interest characterizing the portion of the continuous, spiral-shaped structural feature associated with the one instance of the plurality of device structures based on a trained mapping model.

24. The method of claim 21, wherein the one or more structures illuminated at the measurement spot includes a proxy metrology target of the plurality of proxy metrology targets, and wherein the estimating of the value of the parameter of interest characterizing the portion of the continuous, spiral-shaped structural feature associated with the one instance of the plurality of device structures involves providing the output signals as input to a trained machine-learning based measurement model.
